(19) United States
(12) Patent Application Publication
(10) Pub. No.: US 2013/0076418 A1
(43) Pub. Date: Mar. 28, 2013

(54) System and Method for Calibration of Timing Mismatch for Envelope Tracking Transmit Systems

(71) Applicants: Alexander Belitzer, Muenchen (DE); Gunther Kraut, Egmating (DE)

(72) Inventors: Alexander Belitzer, Muenchen (DE); Gunther Kraut, Egmating (DE)

(73) Assignee: Intel Mobile Communications GmbH, Neubiberg (DE)

(21) Appl. No.: 13/245,995

(22) Filed: Sep. 27, 2011

(51) Int. Cl. H03L 7/00

(52) U.S. Cl. 327/161

(57) ABSTRACT

One embodiment of the present invention relates to a system for calibrating of timing between an amplifier input signal and a modulated supply power. The system includes a supply modulation component, an error metric component, and a delay determiner. The supply modulation component provides the modulated supply power and the amplifier input signal according to an input signal and a set delay signal. The error metric component provides information from a transmitted amplitude signal and a received amplitude signal. The delay determiner generates timing adjustments in the form of the set delay signal from the error metric information.

### BACKGROUND

Power amplifiers are electronic devices that increase (i.e., amplify) the power of an electric signal. Power amplifiers are widely used in low-power communication systems. Typically, a power amplifier is located in the output stage of a transmission chain and is configured to increase the power of a radio frequency (RF) signal before it is transmitted from an antenna.

Communication systems employing power amplifiers may send signals according to certain communication standards (e.g., EDGE, WCMDA, LTE, etc.). Many such communication standards allow for different levels of output-power with different statistics of emission. Therefore, power amplifiers are often operated to generate output signals spanning a wide output power range (e.g., from a low output power to a maximum output power). However, when a power amplifier is operated to output a signal having less than the maximum output power for which the amplifier is designed, the efficiency of the power amplifier decreases.

A variety of techniques can be employed to improve efficiency in power amplifiers. One technique is to lower the DC supply voltage for the power amplifier in order to lower the overall power consumption. However, merely lowering the supply voltage can lead to non linear gains and/or distortions that degrade the output of the power amplifier. Another technique involves load matching between the power amplifier load and an output impedance, which is controlled by an output matching network located at the output of the power amplifier. To retain a high efficiency, the output matching network changes the output impedance when the supply voltage changes. Changing the DC supply voltage without a corresponding change in the output impedance, causes an impedance mismatch that reduces efficiency of the power amplifier. Still another technique is to use envelope tracking to modulate the supply voltage to the output amplifier. The envelope of a signal can be derived by monitoring the signal to be amplified. Then, the envelope can be used to modulate the supply voltage of the amplifier. However, distortions and/or non-linearity can be introduced.

### BRIEF DESCRIPTION OF THE DRAWINGS

FIG. 1 is a block diagram illustrating an envelope tracking transmit system in accordance with an embodiment of the invention.

FIG. 2 is a block diagram illustrating an envelope tracking transmit system in accordance with an embodiment of the invention.

FIG. 3 is a block diagram illustrating delay determiner component 228 in accordance with an embodiment of the invention.

FIG. 4A is a three dimensional graph illustrating gain of a power amplifier.

FIG. 4B is a graph illustrating correlation or mapping of a modulated supply power with an amplifier input power to yield a relatively constant gain value for a power amplifier in accordance with an embodiment of the invention.

FIG. 5 is a graph illustrating example error metrics for timing mismatches in accordance with an embodiment of the invention.

FIG. 6A is a graph depicting an example of a cross correlation of an amplitude transmitted signal and an amplitude received signal in accordance with an embodiment of the invention.

FIG. 6B is a graph illustrating the difference or cross correlation of the peak samples.

FIG. 7 is a graph diagram illustrating a calibration procedure according to an embodiment of the invention.

FIG. 8 is a flow diagram illustrating a method for calibration of timing mismatch in accordance with an embodiment of the invention.

FIG. 9 is a flow diagram illustrating a method for calibration of timing mismatch in accordance with an embodiment of the invention.

### DETAILED DESCRIPTION

The present invention will now be described with reference to the attached drawing figures, wherein like reference numerals are used to refer to like elements throughout, and wherein the illustrated structures and devices are not necessarily drawn to scale.

One embodiment of the present invention relates to a system for calibrating of timing between an amplifier input signal and a modulated supply power. The system includes a supply modulation component, an error metric component, and a delay determiner. The supply modulation component provides the modulated supply power and the amplifier input signal according to an input signal and a set delay signal. The error metric component generates an error metric component according to a transmitted amplitude signal and a received amplitude signal. The delay determiner generates timing adjustments in the form of the set delay signal. Alternate embodiments include a power amplifier that uses the modulated supply power as a power source and generates the output signal from the input signal. In another, any of the above additionally include a coupling device that obtains a received signal from the output signal. In another, any of the above including a measurement device that obtains the received amplitude signal from the received signal. In another, any of the above where the delay determiner calculates an error level from the error metric and determines the set delay signal according to the error level.

Another embodiment of the invention includes a method for calibrating or performing timing alignment. A plurality of negative delays are introduced into a timing alignment between a modulated supply signal and an amplifier input signal for a power amplifier. A plurality of negative delay error levels are obtained based on the plurality of negative delays. A plurality of positive delays are introduced and a plurality of positive delay error levels are obtained. An intercept point is determined based on the above and a timing adjustment is derived based on the intercept point. The timing adjustment can then be introduced to facilitate alignment.

in yet another embodiment, a method for calibrating or performing timing alignment for a power amplifier is disclosed. An initial error level is obtained. A first timing adjustment is introduced between a modulated supply signal and an amplifier input by a first amount in a first direction. A first error level is obtained based on the timing adjustment. If the first error level is larger than the second error level, a second timing adjustment by a second amount in an opposite direction is introduced. In one variation, the first timing adjustment occurs if the initial error level exceeds a threshold amount.

The embodiments of the invention include mitigating power consumption inside power amplifiers for high crest factor modulation types, such as 3GPP, LTE, and HSUPA+ defined systems. The embodiments include supplying a sufficient, yet reduced modulated supply power to a power amplifier that yields a relatively linear transmission of an input signal to an output of the power amplifier. This reduced power with linearity is realized by aligning the timing between for the modulated supply power and the amplifier input for the power amplifier.

The embodiments of the invention can be performed or utilized at production or during regular operation. During regular operation, timing misalignments due to varied operating parameters, including changes in temperature and battery supply, can be corrected. The inventors recognize that power amplifier gain is a function of the modulated power supply, also referred to as Vcc, and the input signal or amplifier input. Thus, the both the power amplifier supply and the input signal should be correct in their amplitude and synchronized in time. For some systems, such as LTE20 systems, the time alignment should be better than 1 nano second.

The inventors recognize that components, including analog components, in various changes in communications systems include production tolerances with varied propagation delay and that this delay changes according to operating conditions, such as temperature and battery voltage. Thus, even if a system is calibrated for production tolerances, the delays can change due to varied operating conditions. As a result of the change in delays, the power amplifier supply and the input signals may not be compatible or synchronized with regard to amplitude and time, thereby yielding non-linear gain or introduction distortions into the output signal.

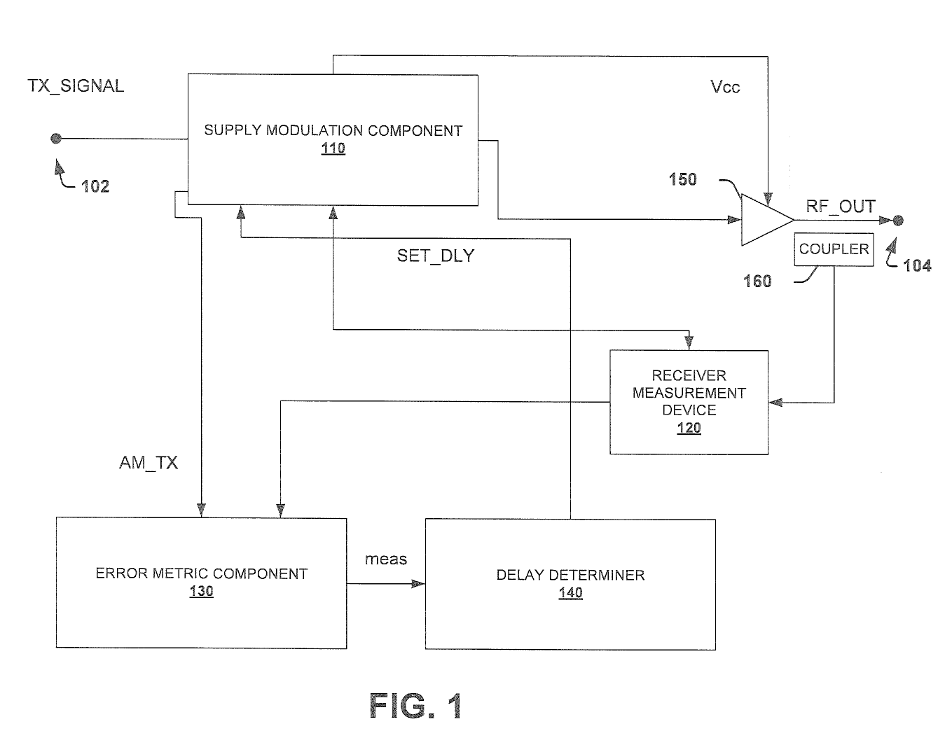

FIG. 1 is a block diagram illustrating an envelope tracking transmit system 100 in accordance with an embodiment of the invention. The system 100 mitigates power consumption by tracking the envelope of a transmit or output signal and adjusting timing for a modulated supply power accordingly.

The system 100 includes a transmit signal input node 102, an output signal node 104, a supply modulation component 110, a receiver measurement device 120, an error metric component 130, a delay determiner/controller 140, a power amplifier 150 and a coupler 160.

The signal input node 102 provides an input signal to be transmitted. The input signal is typically a modulated signal used for communication. In one example, the input signal is at a frequency of between −20 MHz and +20 MHz.

The output signal node 104 provides an output signal to be transmitted. The output signal is generally amplified for transmission. In one example, the output signal is provided to an antenna (not shown) for transmission. The output signal is within a range of suitable frequencies, which in one example includes −20 MHz to +20 MHz.

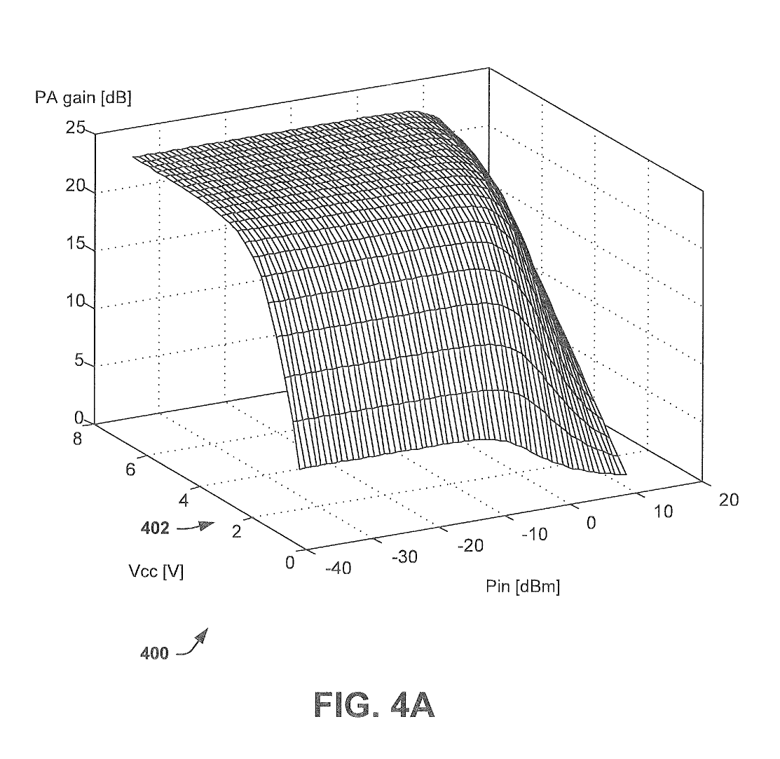

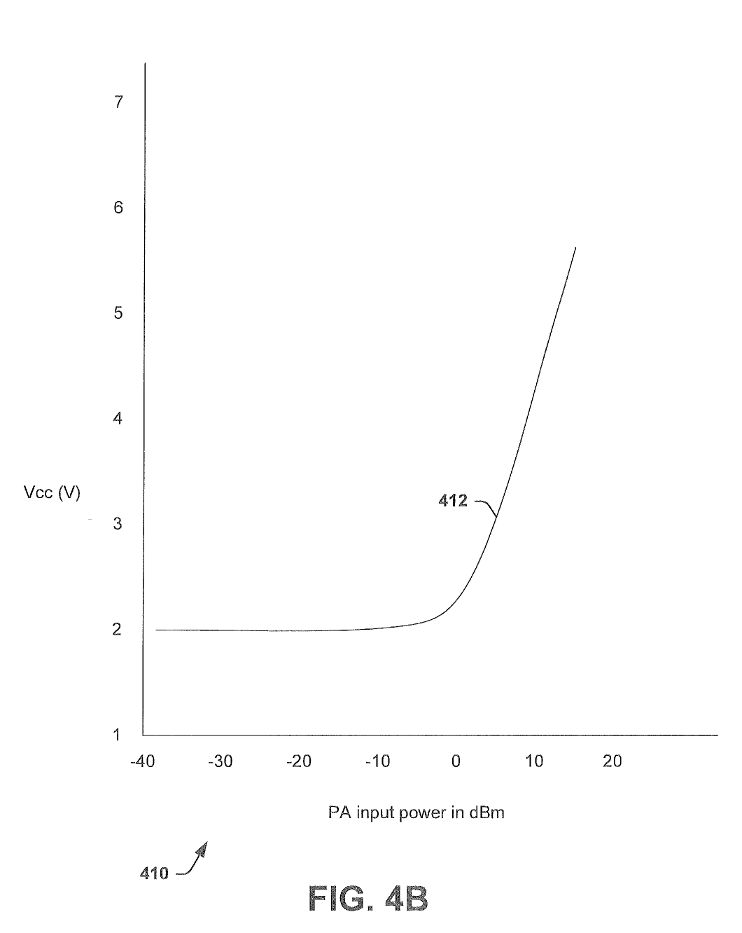

The supply modulation component 110 receives the input signal and a set delay signal (SET_DLY). The supply modulation component 110 generates a modulated supply power, also referred to as Vcc, for use by the power amplifier 150 and an amplifier input signal. The modulated supply power is a modulated signal to reduce power consumption and is aligned with the amplifier input signal to mitigate distortion and maintain a desired or selected gain for the amplifier. The set delay signal includes timing adjustments for the modulated power supply inorder to better align the modulated supply power with the amplifier input signal. Further, the modulated supply power is typically generated with a lower voltage limit in order to maintain the selected gain of the power amplifier 150. The supply modulation component 110 can determine and/or select the lower voltage limit. As a result, the modulated supply mitigates power consumption during operation of the system 100 when compared with prior art systems. FIG. 4B and the description below illustrate an example mapping or alignment of the modulated amplifier supply with the amplifier input signal.

The supply modulation component 110 also provides a transmitted amplitude signal derived from the input signal. The transmitted amplitude signal provides information regarding the amplitude of the input signal over one or more cycles.

The power amplifier 150 receives the amplifier input signal and the modulated supply signal and provides an output signal (RF_OUT). The coupler 160 is coupled to the output signal and provides the coupled output signal, also referred to as a received signal. The coupled output signal is a lower power version of the output signal and CaO be provided by a coupler 160 and simulates the signal that could be received at receivers.

The receiver measurement device 120 receives the coupled output signal and provides measured components. The receiver measurement device 120 analyzes the coupled output signal to generate the measured components. The measured components include amplitude information and the like. The amplitude information is referred to as a received amplitude signal.

The error metric component 130 receives the measured components and also receives the transmit amplitude signal from the supply modulation component 110. The transmit amplitude signal provides information regarding the amplitude of the input signal. The error metric component compares and analyzes the amplitude signal and the measured components to determine an error metric, also referred to as m or meas.

The delay determiner 140 generates the set delay signal (SET_DLY) for use by the supply modulation component 110. The delay determiner receives the error metric and may also receive the measured components. The set delay signal is typically generated with timing adjustments for the modulated supply power that improve alignment with the amplifier input signal. However, it is appreciated that timing adjustments can be included that introduce alignment errors in order to derive other adjustments or calibrate for adjustments. The present invention includes mechanisms for determining the set delay signal, which are described in greater detail below. In one example, error levels are calculated according to one or more mechanisms and timing adjustments are introduced that mitigate or reduce future or subsequent error levels. In another example, a number of samples of received and transmitted amplitude signals are tracked, compared and correlated to identify a suitable timing adjustment that facilitates alignment of the modulated supply power with the amplifier input signal. It is appreciated that variations and alternative mechanisms are contemplated and in accordance with the present invention.

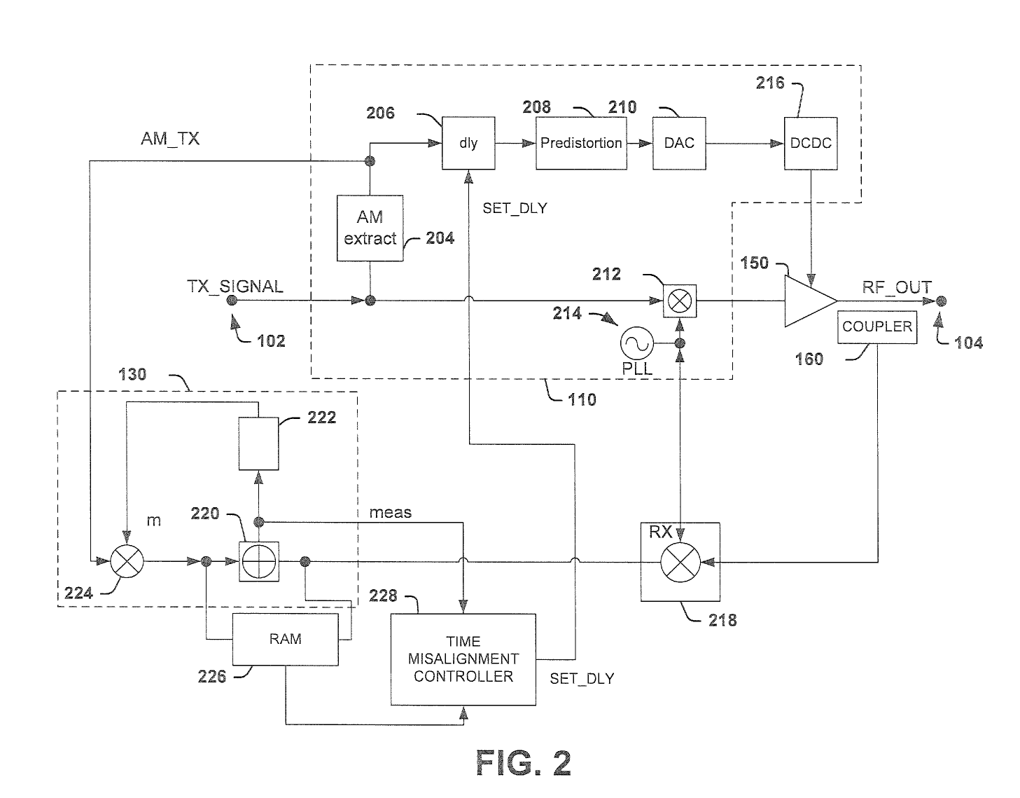

FIG. 2 is a block diagram illustrating an envelope tracking transmit system 200 in accordance with an embodiment of the invention. The system 200 mitigates power consumption by tracking the envelope of a transmit or output signal and adjusting a delay or timing alignment for a modulated supply power for a power amplifier accordingly.

The system 200 includes an input node 102, an output node 104, a power amplifier 150, and an output coupler 160.

The signal input node 102 provides an input signal to be transmitted. The input signal is typically a modulated signal used for communication. In one example, the input signal is at a frequency of between −20 MHz and +20 MHz.

The output signal node 104 provides an output signal that can be amplified and transmitted. The output signal is an RF signal and can be used for communication purposes and the like. In one example, the output signal is provided to an antenna (not shown) for transmission.

The supply modulation component 110 includes an amplitude extract component 204, a delay component 206, a predistortion component 208, a digital to analog converter 210, a mixer 212 and a phase locked loop (PLL) component 214. The amplitude extract component 204 receives the input signal and extracts amplitude information, in the form of a transmitted amplitude signal (AM_TX). Thus, the transmitted amplitude signal includes amplitude information for a signal that will be transmitted. A suitable mechanism can be utilized to extract the amplitude information, such as using a CORDIC algorithm.

The delay component 206 receives the transmitted amplitude signal and delays or adjusts the timing according to a provided set delay signal. The set delay signal includes a timing adjustment amount and a direction of the adjustment, such as forward or back or positive or negative. As a result, the delay component 206 generates a delayed signal according to the transmitted amplitude signal and the set delay signal. The set delay signal includes timing adjustments, which includes adjustment amounts and a direction of the adjustments. In one example, the timing adjustments range from 0 to 100 nsec with a step granularity of ¼ nsec, however it is appreciated that other ranges and granularity values can be employed with the invention. Step size granularity of ¼ nanosecond is generally sufficient for communication systems, such as an LTE20 system.

The predistortion component 208 receives the delayed amplitude signal and distorts the signal by a selected amount to generate a distorted amplitude signal. The amount of distortion is selected to yield a selected or desired gain for the power amplifier 150. In one example, the amount of distortion is selected such that the gain of the power amplifier 150 is set at 20 dB. The digital to analog converter 210 receives the distorted amplitude signal and converts the signal into an analog signal, referred to as analog amplitude signal.

The analog amplitude signal is fed to the DCDC converter component 216. The DCDC converter component 216 is a fast DCDC converter and generates a modulated supply signal for the power amplifier 150. The modulated supply signal is provided as an output of the supply modulation component 110.

The mixer component 212 and the PLL component 214 receive the input signal and provide an amplitude input signal as an output of the supply modulation component 110. As a result, the modulated supply mitigates power consumption during operation of the system 100 when compared with prior art systems.

The power amplifier 150 receives the amplifier input signal and the modulated supply signal and provides an output signal (RF_OUT). The output signal can be further processed and/or provided to an antenna for transmission. The output signal can be utilized for communication purposes and the like.

The coupler 160 is coupled to the output signal and provides the coupled output signal. The coupled output signal is typically a lower power version of the output signal and is generated or provided without substantially impacting the output signal.

The measurement component 218 receives the coupled output signal and provides the measured components. In one example, the measurement component 218 includes a mixer that provides the measured components using the coupled output signal as an input, a signal from the PLL component 214 as an oscillator input signal, and provides the measured components as an output signal. The measured components include a received amplitude signal, which represents amplitude values over time for the output signal as received by receivers.

Error metric component or loop 130 receives the measured components and the transmitted amplitude signal (AM_TX) and derives an error metric, also referred to as m or meas, depending on which point of the loop the value is obtained. An error metric of zero indicates no error, which typically does not occur.

The error metric loop 130, in this example, includes an adder 220, function component 222 and mixer or multiplier 224. The multiplier 224 multiplies the transmitted amplitude signal with an error metric m to yield a multiplied amplitude signal. The adder 220 adds the measured components to the multiplied amplitude signal to create a second error metric, “meas”. The function component 222 then calculates or finds the error metric “m” from the second error metric “meas”. The function component 222 is an error integrator and it finds a proper scaling factor “m”. As long as the difference between the transmitted and the received amplitude signal is greater than zero, the component 222 will adjust its output, changing the value of “m”. Additionally, component 222 also operates as lowpass filtering of the error signal “meas”, even if the error signal is alternating around zero with a high rate, the value “m” will be stabilized by the filtering function of the component 222.

The loop 130 repeats until the error metric, m, and the intermediate error metric, meas, are stabilized or settled. In one example, the error metrics are stabilized after 20-30 micro seconds.

Generally, the greater the misalignment of the synchronization between the modulated supply signal and amplitude input signal, the greater the error values, “m” and “meas”. The error metric loop 130 can be activated continuously, dynamically, or otherwise to yield updated error values to account for changes in operating conditions, such as temperature and power supply.

The time misalignment component 228, also referred to as a delay determiner component, receives one or more of the error metrics and generates a set delay signal SET_DLY to improve alignment of the modulated supply signal and the amplitude input signal. The time misalignment component 228 can utilize a memory device 226 to store previous error metrics and the like. In one example, the time misalignment component calculates error levels and determines timing adjustments according to the error levels. In another example, the time misalignment component 228 obtains samples of the transmitted amplitude signal and the received amplitude signal and correlates the values to identify timing adjustments. In this example, the error metric is not necessarily needed.

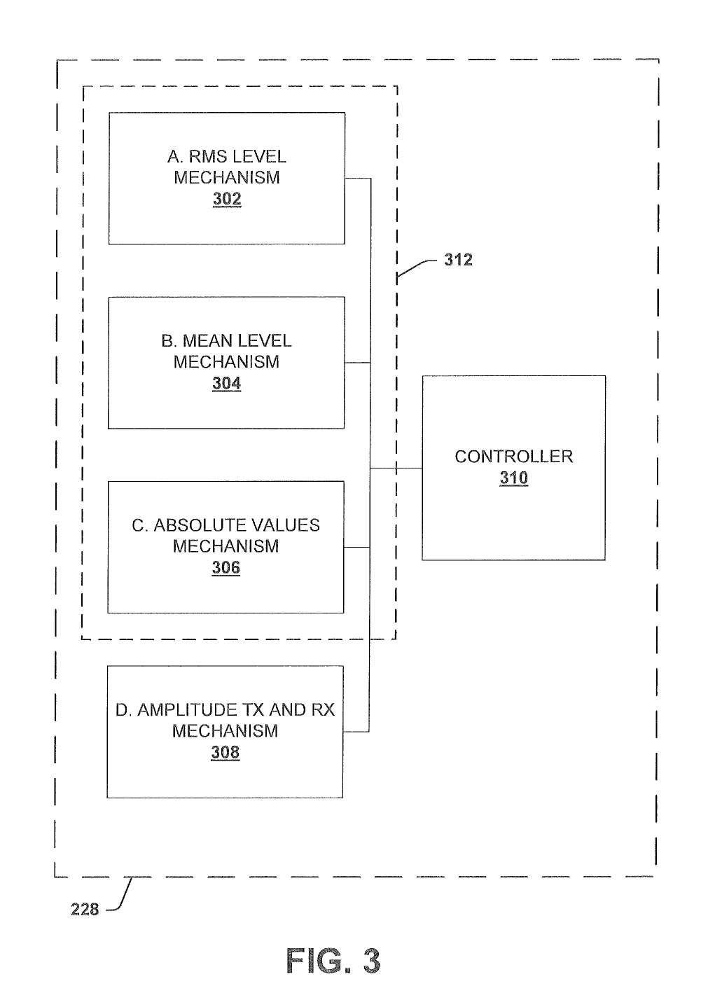

FIG. 3 is a block diagram illustrating delay determiner component 228 in accordance with an embodiment of the invention. It is appreciated that alternate variations of the component 228 shown in FIG. 3 are contemplated and in accordance with the invention.

The delay determiner component 228 utilizes one or more mechanisms to determine a timing adjustment, also referred to as a set delay value, for use in an envelope tracking transmit system. In this example, the delay determiner 228 includes an RMS level mechanism 302, a mean level mechanism 304, an absolute value mechanism 306, an amplitude mechanism 308 and a controller 310. The RMS level mechanism 302, the mean level mechanism 304 and the absolute value mechanism 306 are suitable examples of error level calculating component 312. It is appreciated that other similar mechanisms can be included in addition or instead of the above mechanisms.

The controller 310 interacts with the other components and can control their performance. The controller 310 can also interface with a memory component (not shown). The controller 310 can coordinate the various error level calculations and determine the set delay value and signal with the components 312, including mechanisms 302, 304, and 306 and the amplitude mechanism 308.

The RMS level mechanism 302 derives a set delay signal by calculating and analyzing the root mean square (RMS) of an error signal. The error signal can be provided by a component, such as the error metric loop or component 130, described above. The RMS mechanism 302 calculates an RMS value for a selected period of time or a selected number of cycles. The RMS value is calculated by taking the square root of a mean of the squares of a selected number of error samples of the error signal. Thus, a number of error samples or values are obtained from the error signal, and then the samples are squared to yield squares of the samples. Subsequently, a mean or average value of the squares is calculated. Then, a square root of the mean is obtained to yield the RMS value. The RMS value is correlated to a delay value, and the delay value is utilized to generate the set delay signal, including a direction of the delay signal, such as forward or backward. The delay value is selected to reduce or mitigate the RMS value. It is appreciated that the proper direction is not determined from the RMS value. However, this CaO be overcome by implementing the set delay value in the delay signal and analyzing a next sequence of error samples or values. If the RMS value of the next sequence decreases, it can be assumed the previous direction was appropriate. However, if the RMS value of the next sequence increases, an opposite direction is selected.

The mean level mechanism 304 derives a set delay signal by calculating and analyzing the mean value of the error signal. The mean level mechanism 304 derives a set delay signal by calculating and analyzing the mean value of an error signal. The error signal can be provided by a component, such as the error metric loop or component 130, described above. The mean level mechanism 304 calculates mean value or level for a selected period of time or a selected number of cycles as a mean or average of absolute values of error metrics (meas). In one example, 300 samples were used. In another example, a simple low pass filter is used to calculate the mean value.

The mean value is obtained by calculating the mean or average value for absolute values of the selected number of samples or values from the error signal. The mean value is correlated to a delay value, and the delay value is utilized to generate the set delay signal, including a direction of the delay signal, such as forward or backward. The delay value is selected to reduce or mitigate the mean value. It is appreciated that the proper direction is not necessarily determined from the mean value. However, this can be overcome by implementing the set delay value in the delay signal and analyzing a next sequence of error samples or values. If the mean value of the next sequence decreases, it can be assumed the previous direction was appropriate. However, if the mean value of the next sequence increases, an opposite direction is selected for a next iteration.

The absolute value mechanism 306 derives a set delay signal by calculating and analyzing the absolute value of the error signal. The absolute value mechanism 306 derives the set delay signal by calculating and analyzing the absolute value of an error signal. The error signal can be provided by a component, such as the error metric loop or component 130, described above. The absolute value mechanism 306 calculates an absolute value or level for a selected period of time or a selected number of cycles. In one example, 300 samples were used.

The absolute value is obtained by accumulating absolute values of samples or values from the error signal. In one example, 50 samples were accumulated to generate the absolute value. The absolute value is correlated to a delay value, and the delay value is utilized to generate the set delay signal, including a direction of the delay signal, such as forward or backward. The delay value is selected to reduce or mitigate the absolute value. It is appreciated that the proper direction is not necessarily determined from the absolute value. However, a next sequence of error samples or values can be analyzed to determine whether the adjustment reduced or increase the accumulated absolute value. Thus, if the accumulated absolute value was reduced, the previous direction can be assumed correct. However, if the accumulated absolute value increased, an opposite direction is selected for a next iteration.

The amplitude mechanism 308 derives a set delay signal by cross correlating error metric samples. A selected number of samples or a specified duration of samples are processed. In one example, 50 samples from each signal, with a sampling frequency of 104 Mhz are used. A convolution is performed on the samples to derive the set delay signal. Additionally, it is noted that the amplitude mechanism 308 is also operable to identify the direction of the delay adjustment.

FIG. 4A is a three dimensional graph 400 illustrating gain of a power amplifier. The graph 400 is provided for illustrative purposes only and is provided as a simulation. The graph 400 depicts the gain (PA gain [dB]) on a y-axis, modulated supply signal or power (Vcc [V]) on a z-axis, and amplifier input signal or power (Pin [dBm]) on an x-axis. As an example. FIG. 2 can be referenced for further description of the modulated supply signal or power and the amplifier input signal or power, which are provided to power amplifier 150.

Thus, ideally, the gain should be the same regardless of the value of the modulated supply power and/or the amplifier input power. However, FIG. 4A shows that this is not the case. The amplifier gain drops off on the amplifier input signal dropping beyond a minimum value, which in one example is beyond 0 dBm. Further, the amplifier gain also drops off on the modulated supply power dropping below a minimum voltage, which in one example is about 1.8 Volts. The gain for a power amplifier should be relatively constant. Here, the gain is selected to be at about 23 dB.

As a result, the inventors of the present invention recognize that a minimum voltage or power can be selected or designed for the modulated supply power and the amplifier input signal. Furthermore, it is noted that the graph 400 and information provided are illustrative in nature and that other embodiments of the invention are contemplated that have varied modulated supply signals and amplifier inputs signals and selected gain values.

FIG. 4B is a graph 410 illustrating correlation or mapping of a modulated supply power with an amplifier input power to yield a relatively constant gain value for a power amplifier in accordance with an embodiment of the invention. The graph 410 is provided as an example mapping of the modulated supply power with the amplifier input power for an envelope tracking system, such as the systems described above.

An x-axis depicts amplifier input power, including amplitude modulation, in dBm. A y-axis depicts modulated supply power Vcc in Volts. An example mapping 412 of the two is shown that yields a selected gain for a power amplifier. The selected gain is maintained relatively constant by correlating the modulated supply power with the amplifier input power. Thus, power consumption is mitigated while maintaining the selected gain for the power amplifier. It can be seen in this example that the modulated supply power has a lower limit, of about 1.8 volts in this example, in order to yield the selected gain. Further, it can be seen that the modulated supply power increases exponentially as the amplifier input power exceeds a limit, of about −5 dBm in this example, in order to yield the selected gain.

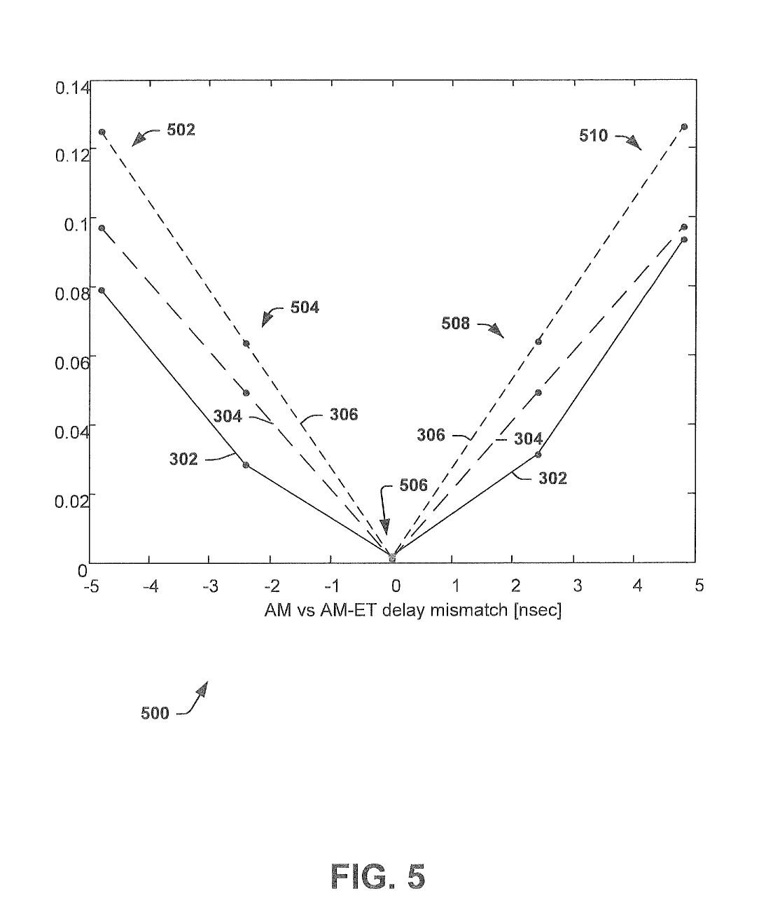

FIG. 5 is a graph 500 illustrating example error levels for timing mismatches in accordance with an embodiment of the invention. Timing between the modulated supply power and the amplifier input was intentionally offset by various amounts of time, ranging from −5 to +5 nsec, in order to see the resulting.

The x-axis depicts induced delay mismatches in nsec and the y-axis depicts error levels obtained via a mechanism of the invention. The error levels include RMS values 302, mean values 304, and accumulated absolute values 306. A description of how the error levels can be obtained and calculated is described above with regard to FIG. 3.

The graph shows several sample points 502, 504, 506, 508 and 510. At sample point 502, where the delay mismatch is set at −5 nsec, the value levels 302, 304, 306 are at about 0.8 or higher. However, the levels do not indicate direction of the delay mismatch.

Sample point 504 corresponds to a delay mismatch set at −2.5 sec. Here, the levels are lower than at sample point 502, but do indicate that there is a time mismatch. Again, the levels at point 504 do not indicate the direction of the time delay mismatch.

Sample point 506 corresponds to no mismatch or a delay mismatch of 0. Here, the levels 302, 304 and 306 are at zero, which is expected. When there is no timing mismatch between the modulated supply power and the amplifier input the error metrics would be at about zero and the error levels, would also necessarily be at about zero.

Sample point 508 is for a timing mismatch of 2.5 nsec. The error levels here are non zero indicating some amount of timing mismatch. Further, the error levels here are similar to those at sample point 504, which is as expected.

The last sample point 510 corresponds to a timing mismatch of 5.0 nsec. The error levels are again non zero indicating a timing mismatch. Additionally, the error levels are similar to those at sample point 502 and are greater than those at 508. It is noted that the error levels do not indicate direction of the timing mismatch.

The graph 500 shows that the error levels do appropriately track variations in timing misalignments. Further, the data can be employed to determine suitable delay adjustments during operation of an envelope tracking transmission system. In one example, the information can be generated and compiled in a lookup table to correlate the error levels to set delay signal adjustments. Thus, an RMS value 302 of about 0.08 can be interpreted to require or suggest a set delay signal adjustment of −5 or +5 nsec.

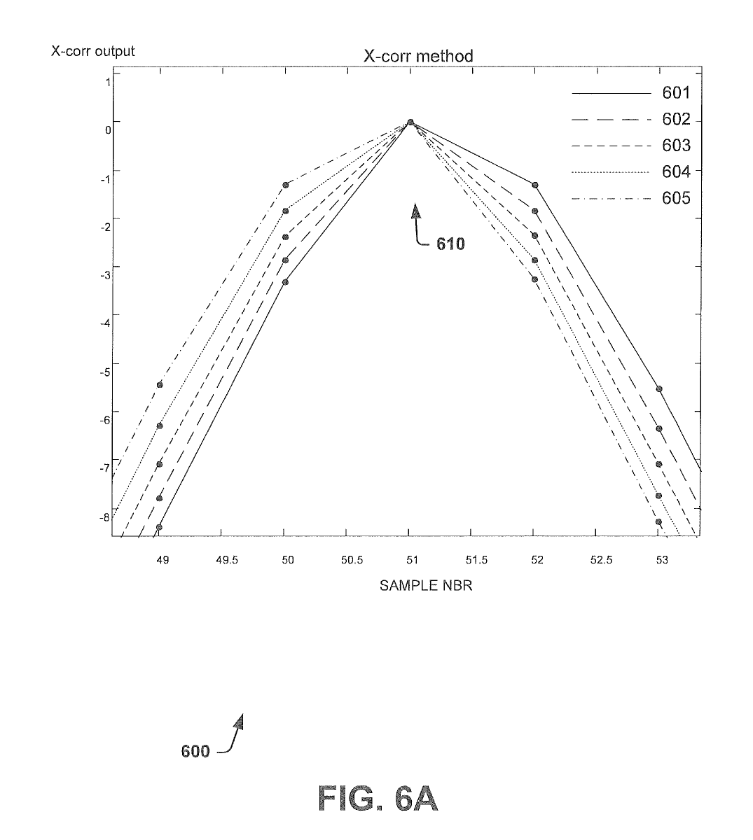

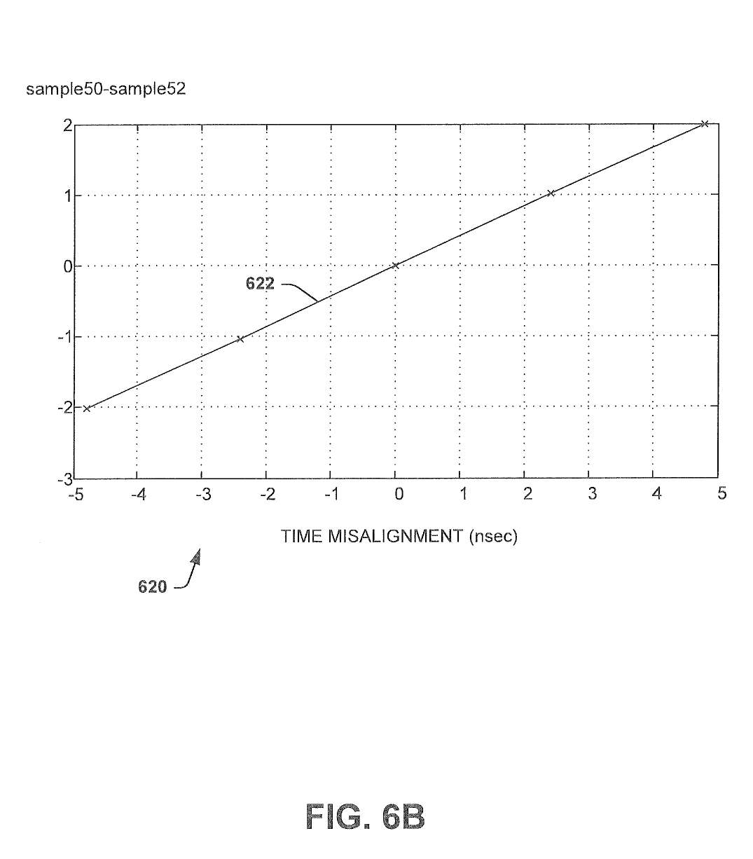

FIG. 6A is a graph 600 depicting an example of a cross correlation of transmitted amplitude and received amplitude samples in accordance with an embodiment of the invention. The graph 600 is provided as an example and it is appreciated that other embodiments of the invention can generate varied samples and correlation information.

The values shown in the graph 600 can be provided using an amplitude correlation mechanism, such as the amplitude mechanism 308 of FIG. 3. Samples of both amplitude signals, the transmitted amplitude signal and the received amplitude signal, are stored in a memory device. The transmitted amplitude signal includes the amplitude information from an input signal to the envelope tracking system. The received amplitude signal includes the amplitude information from a received signal, which can be obtained using a coupler to the output of the power amplifier 150.

In this example, 50 samples of both signals were obtained using a sampling frequency of about 104 MHz. There are lines representing the correlation of the samples for various time delays ranging from −4.8 nsec to 5.8 nsec. Line 601 corresponds to a time mismatch of −4.8 nsec. Line 602 corresponds to a time mismatch of −2.4 nsec. Line 603 corresponds to no timing mismatch, or a time delay mismatch of about zero. Line 604 corresponds to a time mismatch of 2.4 nsec. Line 605 corresponds to a time mismatch of 4.8 nsec.

Thus, cross correlation from one sample point to another can indicate an amount of timing misalignment and a direction of the misalignment. For example, correlating sample number 50 with sample number 52, which are peak samples, shows no change for line 603, which indicates that there is no timing mismatch. As another example, correlating sample number 50 with sample number 52 for line 601 shows that a positive change in direction for the timing is required. The difference between the peak samples is proportional to the amount of timing misalignment present. Similarly, correlating sample number 50 with sample number 52 for line 605 shows that a negative change in alignment is required.

The peak samples are identified according to a number of samples and an expected sample delay. The peak samples are located about a peak position and with a time duration variation from the peak position greater than an expected sample delay. The number of samples refers to how many points of the signals we use for cross correlation. Using a greater number of samples can lead to a more robust result and be more resistance against noise, however the greater number of samples requires more computing effort and resources. The expected sample delay is expected misalignment for the system. Typically, the expected sample delay covers a time period of one to two samples.

The graph 600 can be utilized to generate lookup information for determining delay or alignment adjustments for envelope tracking systems. The peak samples are identified and then a slope between the peak samples is determined. The amount of slope corresponds to an amount of timing alignment adjustment that is needed. The sign of the slope indicates whether the alignment is in the positive or negative direction.

Additionally, the difference in the peak samples for the intentional timing misalignments 601-605 can be plotted to derive a linear relationship between the difference in peak samples and the timing misalignment.

FIG. 6B is a graph 620 illustrating the difference or cross correlation of the peak samples. The graph 620 is derived from the samples utilized for the graph 600 of FIG. 6A. An x-axis depicts time misalignment in nsec and a y axis depicts cross correlation of peak samples.

Cross correlation values from the 5 intentional alignments of FIG. 6A are plotted to yield the line 622. For example, the time delay of −4.8 nsec resulted in a cross correlation of −2, the time delay of −2.4 nsec resulted in a cross correlation value of about −1, the time delay of 0 nsec (no misalignment) resulted in a cross correlation value of about 0, the time delay of +2.4 nsec resulted in a cross correlation of about 1, and the time delay of +4.8 nsec resulted in a cross correlation of about 2.

The linear relationship between the time misalignment and the cross correlation values can be seen. The relationship can be used in operation to correct timing misalignment by using the relationship to convert peak sample cross correlation values into set delay values in order to improve alignment. It is noted that the set delay values yielded also include direction of the adjustment.

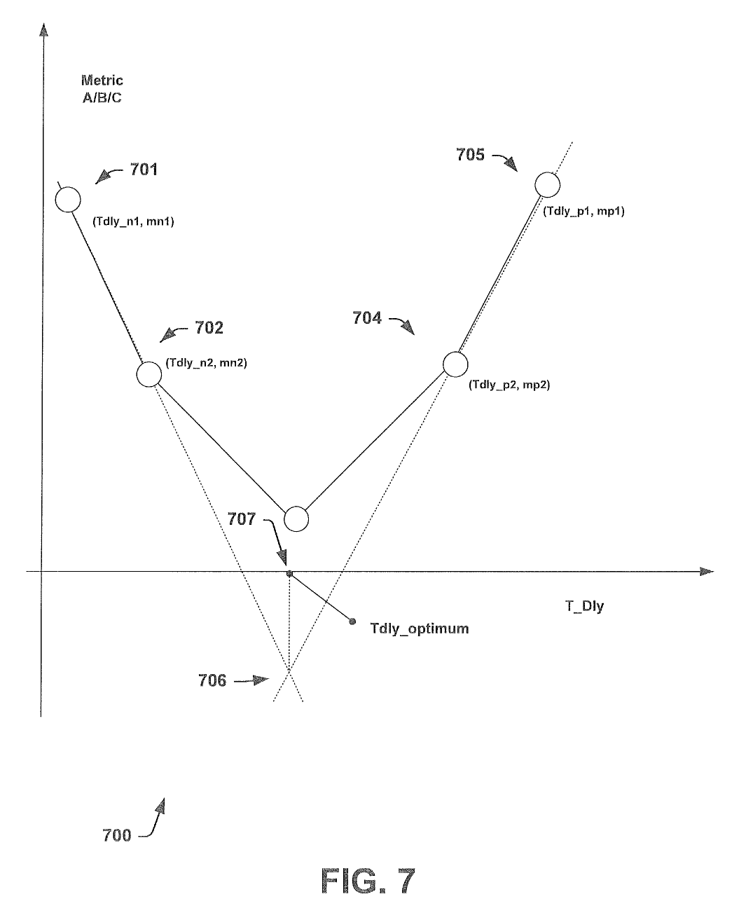

FIG. 7 is a graph diagram illustrating a calibration procedure according to an embodiment of the invention. An x-axis depicts alignment delay and a y-axis depicts error level values.

The calibration procedure utilizes one or more of the error levels, such as those determined by components 302, 304 and 304 of FIG. 3. The error level(s) include, in one example, an RMS error level, a mean error level, and/or an accumulated error level. To facilitate understanding, the calibration procedure can be read in conjunction with the system of FIG. 2.

The calibration procedure begins by adjusting the set delay signal to a high negative delay and determining a first negative error level, which yields a measure of the misalignment. The high negative delay value is a value outside a range of expected or possible timing misalignments. Using a high negative delay makes it likely that timing misalignment is introduced and that the misalignment is negative. The high negative delay and the first error level can be plotted as a first point 701 on the graph 700. The set delay signal is adjusted to a second high negative delay value and a second negative error level is obtained. The second negative delay value and the second negative error level are plotted as a second point 702 on the graph 700.

The set delay signal is then adjusted to a first relatively high positive delay and a first positive error level is obtained. The relatively high positive delay is selected to fall outside a range of expected or possible timing misalignments. The first positive delay and the first positive error level are plotted as a third point 704 on the graph 700. The set delay signal is again adjusted to a second relatively high positive delay and a second positive error level is obtained. The second positive delay and the second positive error level are plotted as fourth point 705 on the graph 700.

The negative delay points 701 and 702 are connected by a straight line and the positive delay points 704 and 705 are connected by a second straight line. An interception point of the two lines 706 yields a suitable setting 706 for the set delay signal to mitigate mismatch.

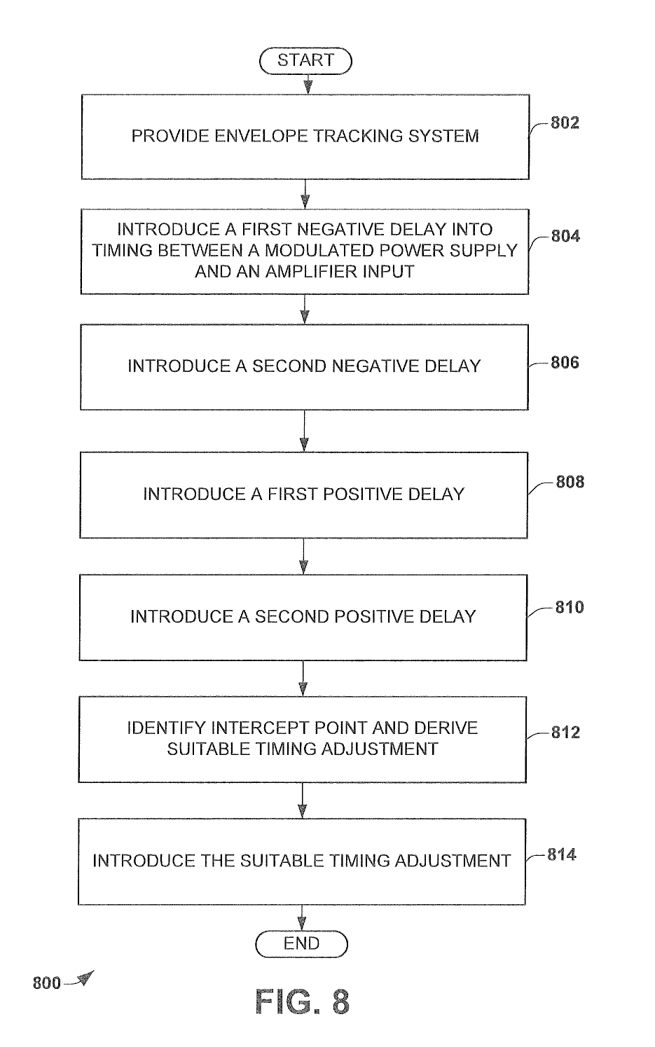

FIG. 8 is a flow diagram illustrating a method 800 for calibration of timing mismatch in accordance with an embodiment of the invention. The method follows the examples provided in FIG. 7. The method 800 involves deliberately mistuning thereby making the method suitable for production calibration procedures, initial use, and the like.

The method begins at block 802, where an envelope tracking transmission system is provided. Examples of suitable transmission systems are shown in FIGS. 2 and 3. A first negative delay is introduced into the timing between the modulated supply power and the amplifier input and a first negative error level is obtained at block 804. The first negative delay is selected to fall outside a range of expected or likely timing misalignments for the system. The first negative error level can include an RMS error level, a mean error level, an accumulated absolute value error level, and the like. Examples of obtaining error levels are provided supra.

A second negative delay is introduced into the timing and a second negative error level is obtained at block 806. In one example, the second negative delay is greater in magnitude than the first negative delay. In another example, the second negative delay is less in magnitude than the first negative delay.

A first positive delay is introduced into the timing and a first positive error level is obtained at block 808. The magnitude of the first positive delay is about equal to the magnitude of the first negative delay. Continuing, a second positive delay is introduced into the timing and a second positive error level is obtained at block 810. The magnitude of the second positive delay is about equal to the magnitude of the second negative delay.

An interception point is identified and an optimum or suitable timing delay is derived from the interception point at block 812. The interception point is identified by defining two lines based on the positive delays and the negative delays. The two lines intersect at an intercept point. Then, the suitable timing delay is obtained by finding a timing delay value that corresponds to the intercept point.

The suitable timing delay is introduced into the system at block 814. The suitable timing delay should mitigate distortions and facilitate alignment of the modulated supply power and the amplifier input signal. This can be verified by obtaining a current error level and comparing the current error level with a previous error level obtained prior to initiating the intentional misalignments.

It is appreciated that variations of the method 800 are contemplated and in accordance with the invention. In one variation, more than two negative and positive timing misalignment values are introduced to yield more error level values and to generate the intercept point. In another variation, the method 800 is initiated on an error level being above a threshold value. In yet another variation, the method 800 is initiated periodically. Further, the method 800 can be repeated iteratively until an error level falls below a threshold amount.

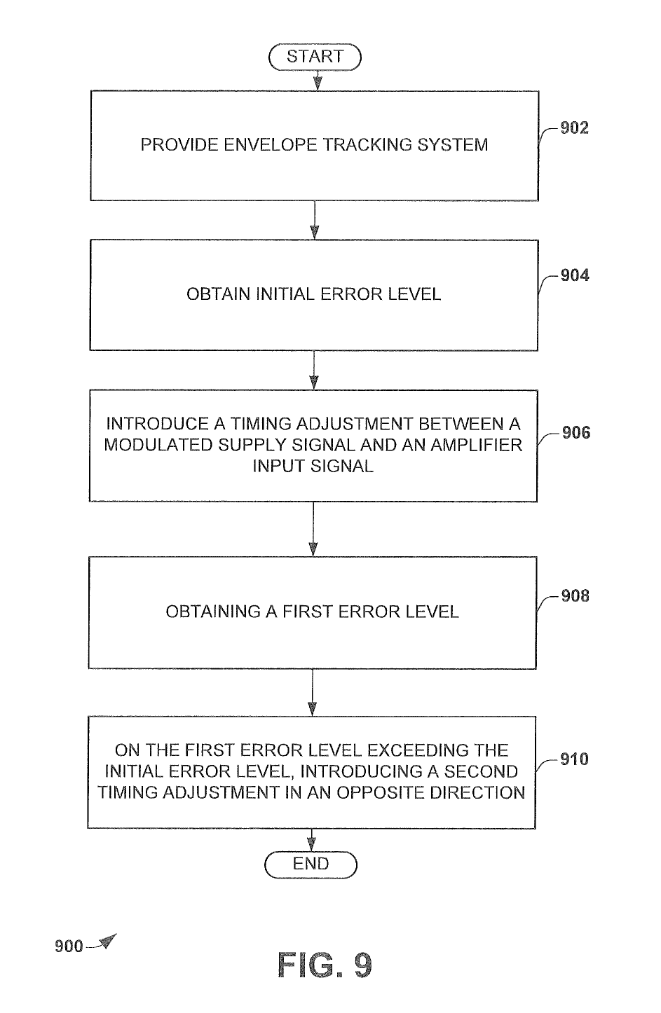

FIG. 9 is a flow diagram illustrating a method 900 for calibration of timing mismatch in accordance with an embodiment of the invention. The method 900, unlike method 800, does not involve deliberately mistuning. The method 900 does utilize error levels.

The method 900 begins at block 902, where an envelope tracking transmission system is provided. Examples of suitable transmission systems are shown in FIGS. 2 and 3. An error level is measured or obtained at block 904. The error level includes one or more of an RMS error level, a mean error level, and an accumulated value error. The measured error level is compared with previous error levels at block 906 to determine if the error level is increasing, decreasing or staying relatively constant.

On the measured error level increasing, a timing alignment between a modulated power supply and an amplifier input is adjusted by a first amount in a first direction at block 908 and the error value is measured again. The first amount is a relatively small amount. An example of a small amount is between 0.5 and 1 nsec. Generally, the small amount is a value as larger or big as the system can utilize without substantially degrading transmission performance during active operation. Thus, for smaller bandwidth systems, like HSUPA+, the small amount can be increased by the same factor as bandwidth is decreased.

If the measured error level decreases, the first direction was the proper direction and another timing adjustment in the first direction can be performed to further reduce the error level. If the error level increases, the first direction was the wrong direction and the timing alignments is adjusted by a second amount in a second direction, which is opposite the first direction at block 910. The second amount is also a relatively small amount. In one example, the second amount is about equal to the first amount. In another example, the second amount is about twice the first amount.

Although the invention has been illustrated and described with respect to one or more implementations, alterations and/or modifications may be made to the illustrated examples without departing from the spirit and scope of the appended claims.

In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A system for calibration of timing mismatch, the system comprising:
a supply modulation component configured to receive an input signal and a set delay signal and provide a modulated supply power and an amplifier input signal according to the input signal and the set delay signal; and
a power amplifier configured to generate an output signal from the input signal and the modulated supply power; and
a delay determiner configured to generate the set delay signal to adjust timing alignment of the modulated supply power and the input signal.

2. The system of claim 1, further comprising an error metric component configured to receive a transmitted amplitude signal and a received amplitude signal and to provide information to the delay determine to facilitate generation of the set delay signal.

3. The system of claim 1, wherein the supply modulation component derives the transmitted amplitude signal from the input signal.

4. The system of claim 3, further comprising a coupling device that obtains a received signal from an output signal.

5. The system of claim 4, further comprising a measurement device that obtains the received amplitude signal from the received signal.

6. The system of claim 2, wherein the error metric component provides an error metric as the information and the delay determiner calculates an error level from the error metric.

7. The system of claim 6, wherein the error level comprises a root mean square value based on a selected number of error metrics.

8. The system of claim 6, wherein the error level comprises a mean value computed according to a selected number of error metrics.

9. The system of claim 6, wherein the error level comprises an accumulated absolute value of a selected number of error metrics.

10. The system of claim 6, wherein the delay determiner adjusts the set delay signal only on the error level increasing above a threshold value.

11. The system of claim 6, wherein the delay determiner adjusts the set delay signal periodically.

12. The system of claim 6, wherein the delay determiner performs a calibration procedure that intentionally misaligns the modulated supply power and the amplifier input signal to derive an error level relationship between a range of error levels and a range of time adjustments.

13. The system of claim 12, wherein the delay determiner utilizes the error level relationship to adjust the set delay signal according to the error level.

14. The system of claim 12, wherein the delay determiner collects a number of samples, identifies peak samples, performs a correlation of the peak samples, and develops a correlation relationship from the correlation of the peak samples.

15. A method for calibrating timing alignment comprising:
introducing a plurality of negative delays into a timing alignment between a modulated supply signal and an amplifier input signal;
obtaining a plurality of negative delay error levels based on the plurality of negative delays;
introducing a plurality of positive delays into the timing alignment;
obtaining a plurality of positive delay error levels based on the plurality of positive delays; and
identifying an intercept point based on the plurality of negative delays, the plurality of negative delay error levels, the plurality of positive delays, and the plurality of positive delay error levels.

16. The method of claim 15, further comprising deriving a timing adjustment for the timing alignment based on the intercept point.

17. The method of claim 15, wherein the plurality of negative delays includes a first negative delay and a second negative delay and the plurality of positive delays includes a first positive delay and a second positive delay, wherein the first positive delay and the first negative delay have substantially similar magnitudes.

18. The method of claim 15, wherein the plurality of negative delays are selected to be outside a range of likely misalignments.

19. A method for calibrating timing alignment for a power amplifier, the method comprising:
obtaining an initial error level;
introducing a timing adjustment between a modulated supply signal and an amplifier input signal by a first amount in a first direction;
obtaining a first error level based on the first amount in the first direction; and
on the first error level being larger than the initial error level, introducing a second timing adjustment by a second amount in a second direction opposite the first direction.

20. The method of claim 19, wherein introducing the timing adjustment occurs on the initial error level exceeding a threshold amount.
